(19) United States
(12) Patent Application Publication
(10) Pub. No.: US 2015/0251278 A1
(43) Pub. Date: Sep. 10, 2015

(54) SOLDER BALL AND CIRCUIT BOARD INCLUDING THE SAME

(71) Applicant: SAMSUNG ELECTRO-MECHANICS CO., LTD., Suwon (KR)

(72) Inventors: Jae Ean LEE, Busan (KR); Jung Hyun CHO, Suwon (KR); Kyung Hwan KO, Yeongi (KR); Yong Ho BAEK, Seoul (KR)

(73) Assignee: SAMSUNG ELECTRO-MECHANICS CO., LTD., Suwon (KR)

(21) Appl. No.: 14/448,150

(22) Filed: Jul. 31, 2014

(30) Foreign Application Priority Data
Mar. 10, 2014 (KR) 10-2014-0027745

(51) Int. Cl. B23K 35/02; H05K 1/18; B23K 35/24

(52) U.S. Cl. CPC B23K 35/0244; B23K 35/24; H05K 1/181

(57) ABSTRACT

A solder ball has a core, an intermediate layer, and a surface layer. In one aspect, the intermediate layer melts at a temperature higher than that of the surface layer. In another aspect, the core is made of a material that maintains a liquid state through a temperature range of from about 20° C. to about 110° C., the intermediate layer is made of a material that maintains a solid state at temperatures up to about 270° C., and the surface layer is made of a material with a melting temperature of about 230° C. to about 270° C. In another aspect, the first metal and the second metal are materials that do not form an intermetallic compound with another material in the solder ball. The solder ball may be used in a circuit board.

### CROSS-REFERENCE TO RELATED APPLICATIONS

This application claims the foreign priority benefit under 35 U.S.C. Section 119 of Korean Patent Application Serial No. 10-2014-0027745, filed Mar. 10, 2014, in the Korean Intellectual Property Office, which is hereby incorporated by reference in its entirety into this application.

### BACKGROUND

1. Field

Embodiments of the present invention relate to a solder ball and a circuit board including the same.

2. Description of the Related Art

According to the trend of miniaturization, slimming, and lightening of various electronic products such as smartphones, tablet PCs, and notebooks, the various electronic components that are mounted inside such electronic products, including components such as circuit boards, CPUs, communication chips, and memory devices, should also become smaller. At the same time, according to the high performance trends of the electronic components, density of devices or wiring is increasing.

Meanwhile, as for a bump-forming processes used to couple electronic components such as package components to a circuit board or to couple the circuit boards to each other, there is also a need for new paradigm technologies.

In a conventional bump forming process of a semiconductor flip chip PCB, a printing method using a solder paste (SP) has mainly been used. This conventional printing method uses a paste type SP containing a flux in which small metal particles and organic matters are mixed.

However, according to the trend of miniaturization of the bump pitch, there are problems such as generation of a bump bridge due to smearing of the flux when printing the SP.

In order to overcome these problems, a micro-ball mounting method is proposed. This micro-ball mounting method is advantageous to implementation of a fine bump pitch and has an advantage that the uniformity of size or height of a bump is high.

Meanwhile, this micro-ball is made of materials having compositions such as Sn—Ag—Cu and Sn—Cu. These materials are widely used to implement a SP or solder ball.

However, when an electronic component such as a silicon die that is vulnerable to stress is coupled to a conventional solder ball made of the above-described materials, the electronic component such as the silicon die may crack.

Accordingly, there is an increasing demand for the development of means for effectively buffering stress generated in a coupling process.

### CITATIONS

U.S. Pat. No. 6,756,687 B1

U.S. Pat. No. 4,463,059 B1

### SUMMARY

One aspect of the present invention is to address the above-described problems and to provide a solder ball that can efficiently buffer stress generated in a coupling process.

Another aspect of the present invention is to provide a circuit board that can reduce a defective rate due to crack even after going through a coupling process using a solder ball.

Benefits of the present invention are not limited to addressing the above-described problems; other technical aspects that are not described above would be clearly understood by those skilled in the art through the following description.

In accordance with one aspect of the present invention, there is provided a solder ball including: a core made of a material that maintains a liquid state at about 20° C. to about 110° C.; an intermediate layer made of a material that maintains a solid state at a temperature below about 270° C.; and a surface layer made of a material with a melting temperature of about 230° C. to about 270° C.

At this time, the material forming the intermediate layer may be a metal that does not form an intermetallic compound with the material forming the core in a temperature condition of about 20° C. to about 270° C.

Further, the material forming the intermediate layer may be a metal that does not form an intermetallic compound with the material forming the surface layer in a temperature condition of about 20° C. to about 270° C.

Further, the material forming the intermediate layer may be a metal that does not form an intermetallic compound with the material forming the surface layer in a temperature condition of about 20° C. to about 270° C.

Further, the material forming the core may include at least one material selected from Ga and Cs.

Further, the material forming the core may include at least one material selected from Ga—Al, Ga—Bi, Ga—In, Ga—Sn, Ga—Zn, Ga—Zn—Sn, Bi—Pb—Sn, Bi—Pb—Sn—Cd, Bi—Pb—In—Sn—Cd, and Bi—Pb—In—Sn—Cd—Ti.

Further, the material forming the core may include at least one material selected from Ga, Cs, Ga—Al, Ga—Bi, Ga—In, Ga—Sn, Ga—Zn, Ga—Zn—Sn, Bi—Pb—Sn, Bi—Pb—Sn—Cd, Bi—Pb—In—Sn—Cd, and Bi—Pb—In—Sn—Cd—Ti, and the material forming the intermediate layer may include at least one material selected from Al, Zn, and Pb.

Further, the material forming the surface layer may include Sn.

In accordance with another aspect of the present invention, there is provided a circuit board including: a solder ball according to the above-described aspect provided on at least one surface thereof; and a conductive pattern.

Further, at least one selected from an active device, a passive device, a printed circuit board, and a semiconductor package may be coupled to the solder ball.

In accordance with another aspect of the present invention, there is provided a solder ball including: a core made of a first metal; an intermediate layer made of a second metal; and a surface layer made of a third metal, wherein the first metal and the second metal may be materials that do not form an intermetallic compound in a temperature condition of about 20° C. to about 270° C.

At this time, the core may be made of a material that maintains a liquid state at about 20° C. to about 110° C., the intermediate layer may be made of a material that maintains a solid state at a temperature below about 270° C., and the surface layer may be made of a material with a melting temperature of about 230° C. to about 270° C.

Further, the intermediate layer may be provided to cover the outside of the core, and the surface layer may be provided to cover the intermediate layer.

Further, the material forming the core may include at least one material selected from Ga, Cs, Ga—Al, Ga—Bi, Ga—In, Ga—Sn, Ga—Zn, Ga—Zn—Sn, Bi—Pb—Sn, Bi—Pb—Sn—Cd, Bi—Pb—In—Sn—Cd, and Bi—Pb—In—Sn—Cd—Ti, and the material forming the intermediate layer may include at least one material selected from Al, Zn, and Pb.

Further, the material forming the surface layer may include Sn.

In accordance with another aspect of the present invention, a solder ball includes a core, an intermediate layer, and a surface layer. The intermediate layer having a melting point higher than that of the surface layer and that of the core.

Additional aspects and/or advantages will be set forth in part in the description which follows and, in part, will be apparent from the description, or may be learned by practice of the invention.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a cross-sectional view schematically showing a solder ball in accordance with an embodiment of the present invention;

FIG. 2A is a view showing a material state before a reflow process is performed on the solder ball in accordance with an embodiment of the present invention;

FIG. 2B is a view showing a material state when the reflow process is performed on the solder ball in accordance with an embodiment of the present invention;

FIG. 3A is a cross-sectional view schematically showing a circuit board in accordance with an embodiment of the present invention;

FIG. 3B is a cross-sectional view schematically showing a circuit board in accordance with another embodiment of the present invention;

FIG. 4A is a metal phase diagram schematically showing a state according to the ratio of Ga and Al and temperature;

FIG. 4B is a metal phase diagram schematically showing a state according to the ratio of Ga and Bi and temperature;

FIG. 4C is a metal phase diagram schematically showing a state according to the ratio of Ga and In and temperature;

FIG. 4D is a metal phase diagram schematically showing a state according to the ratio of Ga and Sn and temperature;

FIG. 4E is a metal phase diagram schematically showing a state according to the ratio of Ga and Zn and temperature;

FIG. 5A is a metal phase diagram schematically showing a state according to the ratio of Cs and Sn and temperature;

FIG. 5B is a metal phase diagram schematically showing a state according to the ratio of Bi and Cs and temperature; and

FIG. 5C is a metal phase diagram schematically showing a state according to the ratio of In and Cs and temperature.

### DESCRIPTION OF EMBODIMENTS

Advantages and features of the present invention and methods of accomplishing the same will be apparent by referring to embodiments described below in detail in connection with the accompanying drawings. However, the present invention is not limited to the embodiments disclosed below and may be implemented in various different forms. The embodiments are provided only for completing the disclosure of the present invention and for fully representing the scope of the present invention to those skilled in the art. Like reference numerals refer to like elements throughout the specification.

Terms used herein are provided to explain embodiments, not limiting the present invention. Throughout this specification, the singular form includes the plural form unless the context clearly indicates otherwise. When terms “comprises” and/or “comprising” used herein do not preclude existence and addition of another component, step, operation and/or device, in addition to the above-mentioned component, step, operation and/or device.

For simplicity and clarity of illustration, the drawing figures illustrate the general manner of construction, and descriptions and details of well-known features and techniques may be omitted to avoid unnecessarily obscuring the discussion of the described embodiments of the invention. Additionally, elements in the drawing figures are not necessarily drawn to scale. For example, the dimensions of some of the elements in the figures may be exaggerated relative to other elements to help improve understanding of embodiments of the present invention. The same reference numerals in different figures denote the same elements.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method. Furthermore, the terms “comprise,” “include,” “have,” and any variations thereof, are intended to cover a non-exclusive inclusion, such that a process, method, article, or apparatus that comprises a list of elements is not necessarily limited to those elements, but may include other elements not expressly listed or inherent to such process, method, article, or apparatus.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or non-electrical manner. Objects described herein as being “adjacent to” each other may be in physical contact with each other, in close proximity to each other, or in the same general region or area as each other, as appropriate for the context in which the phrase is used. Occurrences of the phrase “in one embodiment” herein do not necessarily all refer to the same embodiment.

Hereinafter, configurations and operational effects of embodiments of the present invention will be described in detail with reference to the accompanying drawings.

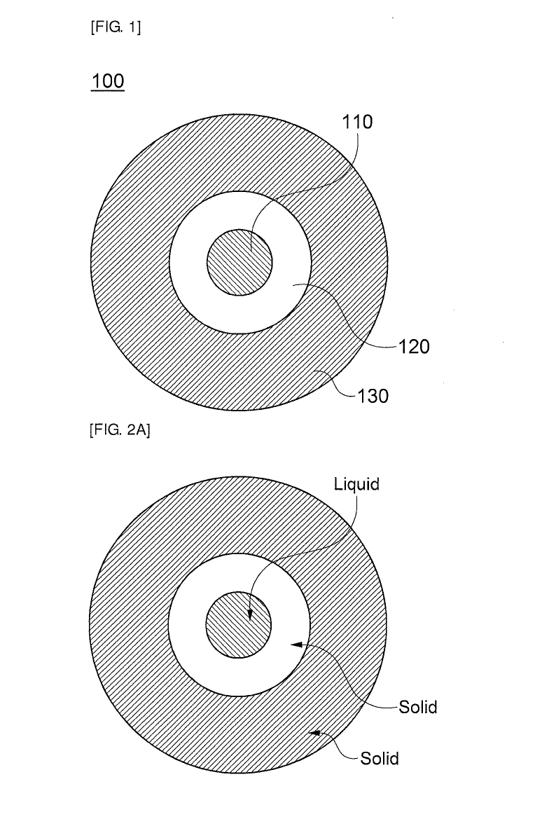

FIG. 1 is a cross-sectional view schematically showing a solder ball 100 in accordance with an embodiment of the present invention.

Referring to FIG. 1, the solder ball 100 according to an embodiment of the present invention may include a core 110, an intermediate layer 120, and a surface layer 130.

At this time, the core 110 may be provided in a center of the solder ball 100, the intermediate layer 120 may be formed to cover an outer surface of the core 110, and the surface layer 130 may be formed to cover the intermediate layer 120.

That is, in an embodiment, the solder ball 100 may be implemented in a three-layer structure consisting of the core 110-the intermediate layer 120-the surface layer 130.

Further, at least one of the core 110, the intermediate layer 120, and the surface layer 130 may have a substantially spherical or oval shape.

Meanwhile, the core 110 may be made of a material that maintains a liquid state at room temperature.

And the intermediate layer 120 may be made of a material that maintains a solid state even in a relatively high temperature environment.

Further, the surface layer 130 may be made of a material that maintains a solid state at room temperature and is changed into a liquid state in a high temperature environment above a predetermined temperature.

In an embodiment, the core 110 may be made of a material that maintains a liquid state at 20 to 110° C., the intermediate layer 120 may be made of a material that maintains a solid state at a temperature below 270° C., and the surface layer 130 may be made of a material with a melting temperature of 230 to 270° C.

A reflow process may be performed in a coupling process using the solder ball 100. At this time, as the reflow process is performed, a hot wind may be provided to a coupling portion to heat the solder ball 100 to a range of 230 to 270° C.

Therefore, the state of the core 110-the intermediate layer 120-the surface layer 130 of the solder ball 100 according to an embodiment of the present invention may be a liquid-solid-solid state before the reflow process and a liquid-solid-liquid state during the reflow process, and return to a liquid-solid-solid state, that is, a state before the reflow process when the reflow process is finished.

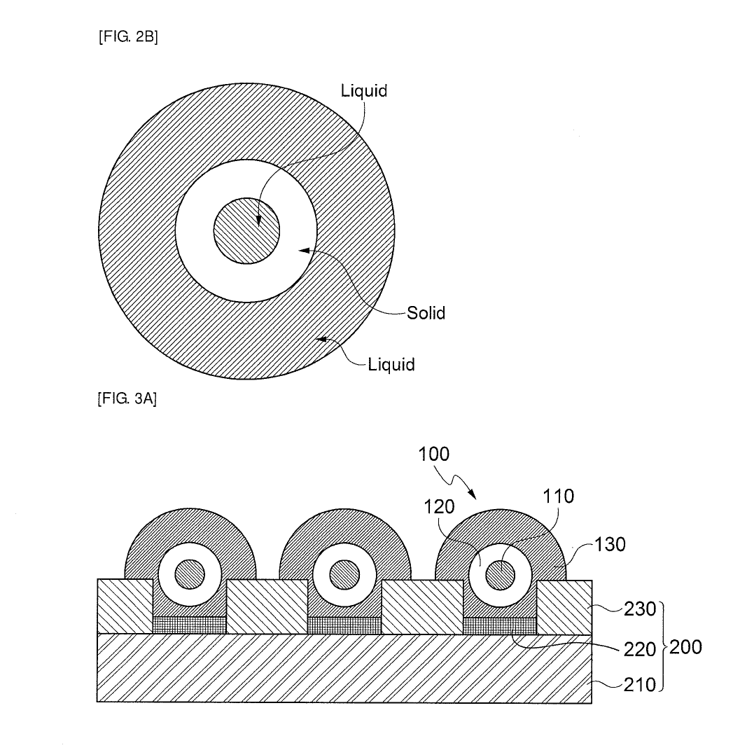

FIG. 2A is a view showing a material state before a reflow process is performed on the solder ball 100 in accordance with an embodiment of the present invention, and FIG. 2B is a view showing a material state when the reflow process is performed on the solder ball 100 in accordance with an embodiment of the present invention.

Referring to FIGS. 2A and 2B, it would be understood that the state of the core 110, the intermediate layer 120, and the surface layer 130 is changed as described above before the reflow process and during the reflow process.

As described above, since the intermediate layer 120 that maintains a solid state even during the reflow process covers the outside of the core 110 that maintains a liquid state at room temperature, it is possible to relax stress due to thermal shock applied to the solder ball 100 and electronic components coupled to the solder ball 100 through the solder ball 100 in the process of performing the reflow process.

Meanwhile, the solder ball 100 according to an embodiment of the present invention may be implemented not to form an intermetallic compound (IMC) inside the solder ball 100 even though the reflow process is performed.

In an embodiment, the intermediate layer 120 may be made of a metal that does not form an IMC with a material that forms the core 110 in a temperature condition of 20 to 270° C.

Further, the intermediate layer 120 may be made of a metal that does not form an IMC with a material that forms the surface layer 130 in a temperature condition of 20 to 270° C.

It is common that the IMC has brittle characteristics. Thus, the ductility of the solder ball 100 may be reduced when the IMC is formed in the solder ball 100 or the stress generated according to the progress of the reflow process may be strongly reflected to the position except the solder ball 100.

Meanwhile, there are efforts to reduce the dielectric loss of electronic components such as a silicon die. Here, in order to reduce the dielectric loss of the silicon die, the silicon die may be implemented with porous Si or the silicon die may be implemented by filling air in the space between Si. However, when the silicon die is implemented in this way, the resistance to stress of the silicon die may be relatively weakened.

Therefore, when the electronic components such as the silicon die having a lower resistance to stress than the solder ball 100 are coupled to a conventional typical solder ball, the electronic components may crack by the stress generated in the coupling process.

However, in the solder ball 100 according to an embodiment of the present invention, the risk of crack of the electronic component coupled to the solder ball 100 may be remarkably reduced due to at least one of the above-described phase change characteristic and the characteristic that the IMC is not formed of the core 110-the intermediate layer 120-the surface layer 130.

That is, in the process of coupling the electronic component etc. using the solder ball 100, the thermal stress generated due to the difference in the coefficient of thermal expansion between different materials may be effectively relaxed.

Meanwhile, in an embodiment, the core 110 may be made of one component material of Ga or Cs. Further, in another embodiment, the core 110 may be made of a material selected from the group consisting of Ga—Al, Ga—Bi, Ga—In, Ga—Sn, Ga—Zn, Ga—Zn—Sn, Bi—Pb—Sn, Bi—Pb—Sn—Cd, Bi—Pb—In—Sn—Cd, and Bi—Pb—In—Sn—Cd—Ti.

These materials have a melting temperature of 11 to 109° C. Therefore, they can maintain a liquid state in a room temperature environment, particularly in a temperature condition of 20 to 110° C.

And a material that forms the intermediate layer 120 may be selected from the group consisting of Al, Zn, and Pb.

Further, the surface layer 130 may be made of a material including Sn.

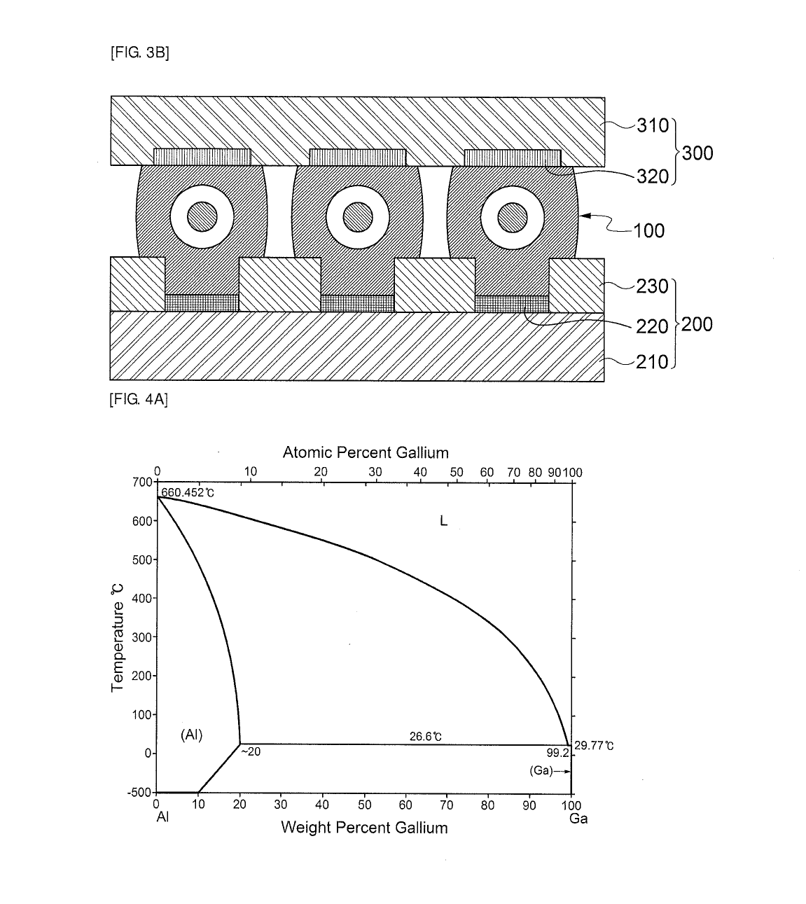

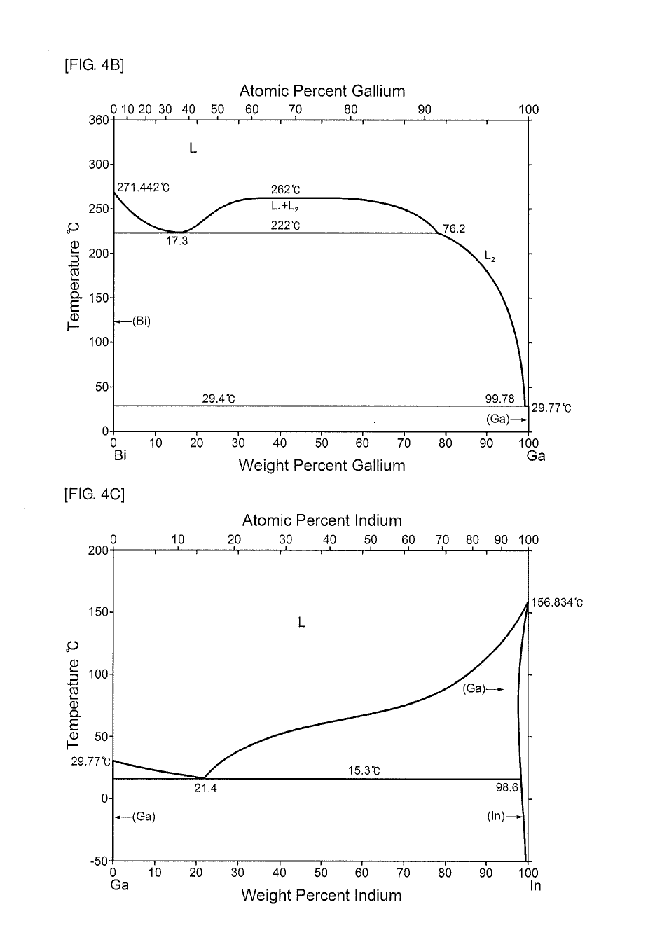

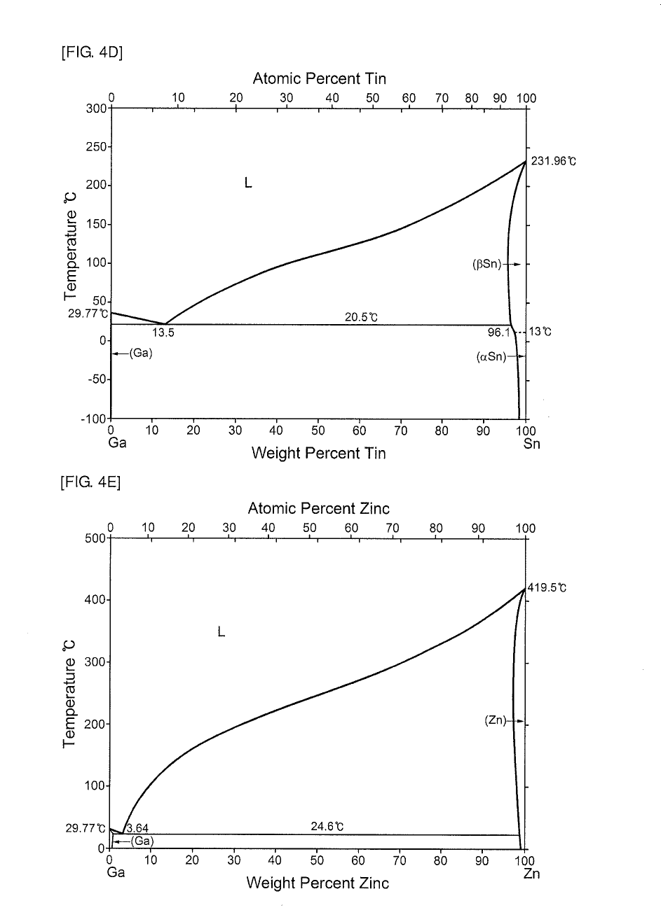

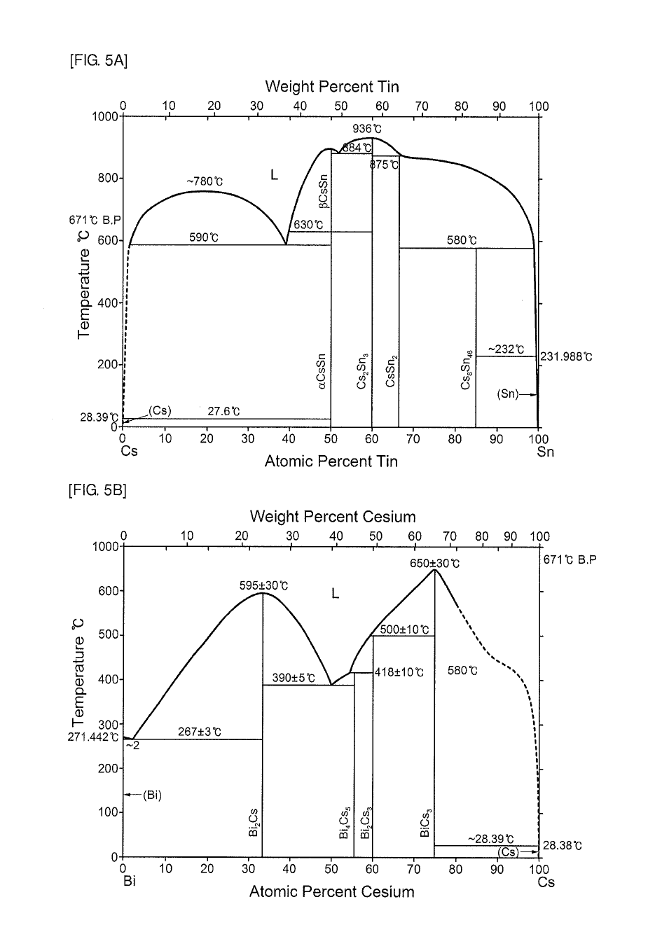

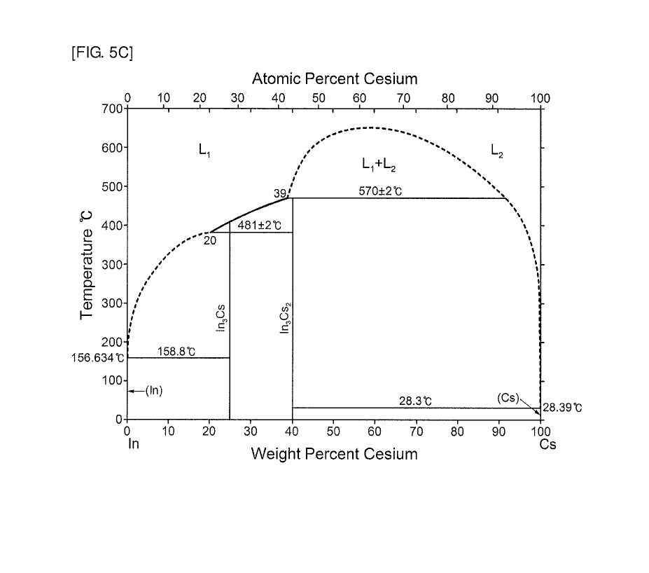

FIGS. 4A to 4E are metal phase diagrams, wherein FIGS. 4A to 4E schematically show a state according to the ratio of Ga and Al and temperature, a state according to the ratio of Ga and Bi and temperature, a state according to the ratio of Ga and In and temperature, a state according to the ratio of Ga and Sn and temperature, and a state according to the ratio of Ga and Zn and temperature, respectively. Further, FIGS. 5A to 5C are metal phase diagrams, wherein FIGS. 5A to 5C schematically show a state according to the ratio of Cs and Sn and temperature, a state according to the ratio of Bi and Cs and temperature, and a state according to the ratio of In and Cs and temperature, respectively.

Referring to FIGS. 4A to 4E, it would be understood that the IMC is not formed in the solder ball 100 when the core 110, the intermediate layer 120, and the surface layer 130 are implemented with the above-described materials. Particularly, the IMC can be not formed even though the solder ball 100 is put in a temperature condition of 270° C. which is a maximum temperature according to the reflow process.

On the other hand, referring to FIGS. 5A to 5C, when the core is implemented with an alloy including Cs, the IMC may be formed in the solder ball. Accordingly, the degree of buffering of the stress, which is generated in the process of coupling an electronic component or a substrate using the solder ball, by the solder ball may be reduced.

FIG. 3A is a cross-sectional view schematically showing a circuit board 200 in accordance with an embodiment of the present invention, and FIG. 3B is a cross-sectional view schematically showing a circuit board 200 in accordance with another embodiment of the present invention.

Referring to FIG. 3A, the circuit board 200 according to an embodiment of the present invention may include the above-described solder ball 100. In an embodiment, the solder ball 100 may be in contact with a first conductive pattern 220 provided on an outer surface of a first substrate 210. At this time, the first conductive pattern 220 may be a solder connection pad. Further, a solder resist 230 may be provided to prevent other regions of the first substrate 210 from being contaminated by the solder ball 100 while exposing at least a portion of the first conductive pattern 220. And the solder ball 100 may be in contact with the solder resist 200 to strengthen the coupling.

Meanwhile, in the drawing, although the first substrate 210 is shown simply, an electronic component may be embedded in the first substrate 210 or the first substrate 200 may have a multilayer structure. Furthermore, in the first substrate 200 having a multilayer structure, circuit patterns made of a conductive material may be further provided on the respective layers or vias for connecting between the layers may be further provided.

Referring to FIG. 3B, in the circuit board 200 according to an embodiment of the present invention, electronic components such as an active device, a passive device, a printed circuit board 300, and a semiconductor package may be coupled to the solder ball 100. That is, one side of the solder ball 100 may be in contact with the first conductive pattern 220 of the first substrate 210, and the electronic component may be coupled to the other side of the solder ball 100.

Although FIG. 3B shows the case in which the electronic component is the printed circuit board 300 including a second substrate 310 and a second conductive pattern 320, it is merely an example and it is apparent that various electronic components can be coupled to the solder ball 100.

However, since the above-described silicon die, particularly the silicon die made of porous Cs or a material in which gas is filled in the space between Cs has a very weak resistance to stress among the electronic components, the effect of preventing cracks may be further highlighted by being coupled through the above-described solder ball 100.

According to an embodiment of the present invention, it is possible to effectively buffer the stress generated in the coupling process using the solder ball.

Further, it is possible to reduce a defective rate due to crack even though the circuit board passes through the coupling process using the solder ball.

Although a few embodiments have been shown and described, it would be appreciated by those skilled in the art that changes may be made in these embodiments without departing from the principles and spirit of the invention, the scope of which is defined in the claims and their equivalents.

What is claimed is:

1. A solder ball comprising:
a core made of a material that maintains a liquid state through a temperature range of from about 20° C. to about 110° C.;
an intermediate layer made of a material that maintains a solid state at temperatures up to about 270° C.; and
a surface layer made of a material with a melting temperature of about 230° C. to about 270° C.

2. The solder ball according to claim 1, wherein through a temperature range of about 20° C. to about 270° C., the material forming the intermediate layer is a metal that does not form an intermetallic compound with the material forming the core.

3. The solder ball according to claim 2, wherein through a temperature range of about 20° C. to about 270° C., the material forming the intermediate layer is a metal that does not form an intermetallic compound with the material forming the surface layer.

4. The solder ball according to claim 1, wherein through a temperature range of about 20° C. to about 270° C. the material forming the intermediate layer is a metal that does not form an intermetallic compound with the material forming the surface layer.

5. The solder ball according to claim 1, wherein the material forming the core comprises at least one material selected from Ga and Cs.

6. The solder ball according to claim 1, wherein the material forming the core comprises at least one material selected from Ga—Al, Ga—Bi, Ga—In, Ga—Sn, Ga—Zn, Ga—Zn—Sn, Bi—Pb—Sn, Bi—Pb—Sn—Cd, Bi—Pb—In—Sn—Cd, and Bi—Pb—In—Sn—Cd—Ti.

7. The solder ball according to claim 1, wherein the material forming the core comprises at least one material selected from Ga, Cs, Ga—Al, Ga—Bi, Ga—In, Ga—Sn, Ga—Zn, Ga—Zn—Sn, Bi—Pb—Sn, Bi—Pb—Sn—Cd, Bi—Pb—In—Sn—Cd, and Bi—Pb—In—Sn—Cd—Ti, and the material forming the intermediate layer comprises at least one material selected from Al, Zn, and Pb.

8. The solder ball according to claim 7, wherein the material forming the surface layer comprises Sn.

9. A circuit board comprising:
a solder ball according to claim 1 provided on at least one surface of the circuit board; and
a conductive pattern.

10. The circuit board according to claim 9, wherein at least one selected from an active device, a passive device, a printed circuit board, and a semiconductor package is coupled to the solder ball.

11. A solder ball comprising:
a core made of a first metal;
an intermediate layer made of a second metal; and
a surface layer made of a third metal,
wherein through a temperature range of about 20° C. to about 270° C., the first metal and the second metal are materials that do not form an intermetallic compound with another material in the solder ball.

12. The solder ball according to claim 11, wherein the core is made of a material that maintains a liquid state through a temperature range of from about 20° C. to about 110° C.,
the intermediate layer is made of a material that maintains a solid state at temperatures up to about 270° C., and
the surface layer is made of a material with a melting temperature of about 230° C. to about 270° C.

13. The solder ball according to claim 12, wherein the intermediate layer is provided to cover the outside of the core, and
the surface layer is provided to cover the intermediate layer.

14. The solder ball according to claim 11, wherein the material forming the core comprises at least one material selected from Ga, Cs, Ga—Al, Ga—Bi, Ga—In, Ga—Sn, Ga—Zn, Ga—Zn—Sn, Bi—Pb—Sn, Bi—Pb—Sn—Cd, Bi—Pb—In—Sn—Cd, and Bi—Pb—In—Sn—Cd—Ti, and
the material forming the intermediate layer comprises at least one material selected from Al, Zn, and Pb.

15. The solder ball according to claim 14, wherein the material forming the surface layer comprises Sn.

16. A solder ball comprising:
a core;
an intermediate layer; and
a surface layer,
the intermediate layer having a melting point higher than that of the surface layer and that of the core.

17. The solder ball according to claim 16, wherein when the solder ball is at room temperature, the core, the intermediate layer, and the surface layer are in a liquid state, a solid state, and a solid state, respectively.

18. The solder ball according to claim 16, wherein when the solder ball is heated to a temperature in a range of about 230° C. to about 270° C., the core, the intermediate layer, and the surface layer are in a liquid state, a solid state, and a liquid state, respectively.

19. The solder ball according to claim 18, wherein the intermediate layer is made of a material that, when the solder ball is heated to the temperature in the range of about 230° C. to about 270° C., does not form an intermetallic compound with a material forming the core and does not form an intermetallic compound with a material forming the surface layer.
